(19) United States
(12) Patent Application Publication
(10) Pub. No.: US 2026/0052821 A1
(43) Pub. Date: Feb. 19, 2026

(54) DISPLAY APPARATUS

(71) Applicant: LG Display Co., Ltd., Seoul (KR)

(72) Inventors: In-Tae KO, Gyeonggi-do (KR); Sang-Moo SONG, Gyeonggi-do (KR); Chang-Seok OH, Gyeonggi-do (KR)

(21) Appl. No.: 19/222,706

(22) Filed: May 29, 2025

(30) Foreign Application Priority Data
Jul. 12, 2024 (KR) 10-2024-0092332

(51) Int. Cl. H10H 29/49; H05K 1/18; H10H 29/855

(52) U.S. Cl. CPC H10H 29/49; H05K 1/189; H10H 29/855; H10H 29/8552; H05K 2201/10128

(57) ABSTRACT

A display device includes a substrate including a display area and a non-display area; a plurality of sub-pixels provided in the display area and arranged in a first direction and a second direction; a first sensing line and a second sensing line provided in the display area; and a first routing line and a second routing line provided in the non-display area, extending in the first direction, and electrically connected to the first sensing line and the second sensing line, respectively; a gate control line provided in the non-display area and extending in the second direction; a ground line provided in the non-display area and extending in the first direction; and a shielding pattern connected to the ground line, wherein the shielding pattern overlaps the first routing line and the gate control line and is disposed between the first routing line and the gate control line in a thickness direction.

### CROSS-REFERENCE TO RELATED APPLICATION

Pursuant to 35 U.S.C. § 119(a), this application claims the benefit of an earlier filing date and right of priority to Korean Patent Application No. 10-2024-0092332 filed on Jul. 12, 2024, the entire contents of which are hereby expressly incorporated by reference into the present application.

### TECHNICAL FIELD

The present disclosure relates to a display device.

### BACKGROUND

As the information society progresses, a demand for different types of display devices increases, and flat panel display devices (FPD) such as liquid crystal display devices (LCD) and organic light-emitting diode display devices (OLED) have been developed and applied to various fields.

A flat panel display device can be widely used for a mobile electronic device such as a smartphone, a computer monitor, or a television. A display panel of a flat panel display device can be supplied by being modularized and commercialized through instruments such as various cases or covers.

### SUMMARY

According to an aspects of the present disclosure, a display device includes a substrate including a display area and a non-display area; a plurality of sub-pixels provided in the display area and arranged in a first direction and a second direction; a first sensing line and a second sensing line provided in the display area; and a first routing line and a second routing line provided in the non-display area, extending in the first direction, and electrically connected to the first sensing line and the second sensing line, respectively; a gate control line provided in the non-display area and extending in the second direction; a ground line provided in the non-display area and extending in the first direction; and a shielding pattern connected to the ground line, wherein the shielding pattern overlaps the first routing line and the gate control line and is disposed between the first routing line and the gate control line in a thickness direction.

It is to be understood that both the foregoing general description and the following detailed description are examples and explanatory and are intended to provide further explanation of the inventive concepts as claimed.

### BRIEF DESCRIPTION OF THE DRAWINGS

FIG. 1 is a schematic plan view of a display device according to an implementation of the present disclosure;

FIG. 2 is a cross-sectional view of a display device according to an implementation of the present disclosure corresponding to line I-I′ of FIG. 1;

FIG. 3 is a schematically enlarged plan view of a display device according to an implementation of the present disclosure corresponding to area E1 of FIG. 1;

FIG. 4 is a schematically enlarged plan view of a display device according to an implementation of the present disclosure corresponding to area E2 of FIG. 3;

FIG. 5 is a cross-sectional view of line II-II′ of FIG. 4;

FIG. 6 is a cross-sectional view of line III-III′ of FIG. 4;

FIG. 7 is a schematic plan view of a display device according to an implementation of the present disclosure applied to a vehicle; and

FIG. 8 is a schematic cross-sectional view of a display device according to an implementation of the present disclosure applied to a vehicle.

### DETAILED DESCRIPTION

The display panel of the flat panel display device can include a display area displaying an image and a non-display area at a periphery of the display area. The case or cover in the front of the display device can cover the non-display area. Here, a portion of the case or cover covering the non-display area can be a bezel area of a product.

The bezel area is an area where an image is not displayed. The bezel area increases the size of the product and degrades the appearance of the product.

Accordingly, implementations of the present disclosure are directed to a display device that substantially obviates one or more of the problems due to limitations and disadvantages of the related art.

An aspect of the present disclosure is to provide a display device with a minimized bezel area.

Another aspect of the present disclosure is to provide a display device capable of reducing power consumption and achieving low power consumption by increasing efficiency.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

Advantages and features of the present disclosure and methods for achieving them will be made clear from implementations described in detail below with reference to the accompanying drawings. The present disclosure can, however, be implemented in many different forms and should not be construed as being limited to the implementations set forth herein, and the implementations are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing the implementations of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein or may be briefly discussed.

When terms such as “including,” “having,” “comprising” and the like mentioned in this disclosure are used, other parts can be added unless the term “only” is used herein. Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure.

Features of various implementations of the present disclosure can be partially or entirely united or combined with each other, technically various interlocking and driving are possible, and each of the implementations can be independently implemented with respect to each other or implemented together in a related relationship.

Hereinafter, examples of implementations of the present disclosure will be described in detail with reference to accompanying drawings.

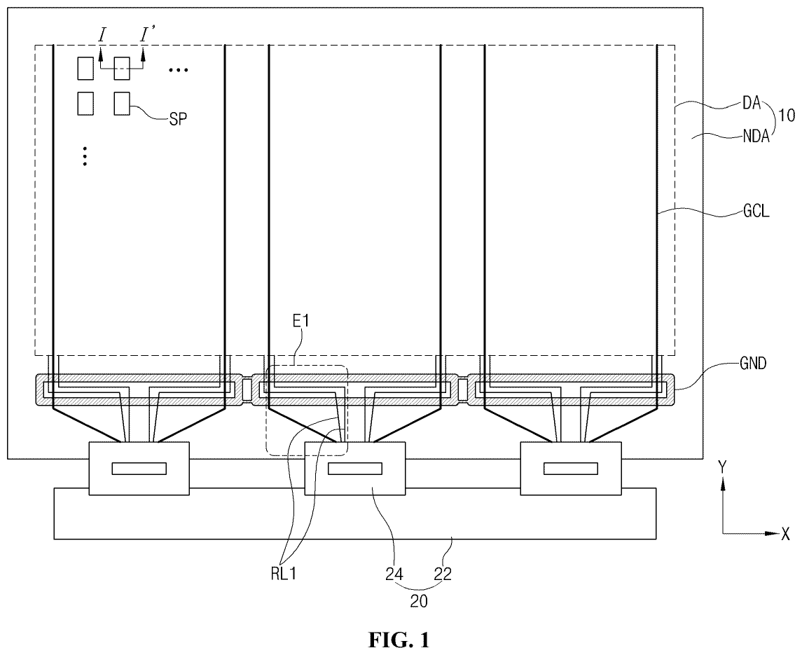

FIG. 1 is a schematic plan view of a display device according to an implementation of the present disclosure.

In FIG. 1, the display device according to an implementation of the present disclosure can include a display panel 10 and a driving unit 20.

The display panel 10 can include a display area DA displaying an image and a non-display area NDA provided on at least one side of the display area DA. For example, the non-display area NDA can surround the display area DA.

A plurality of sub-pixels SP can be provided in the display area DA and be arranged in a first direction X and a second direction Y. Each sub-pixel SP can include at least one thin film transistor and a light-emitting diode.

Each sub-pixel SP can display one color, and the sub-pixels SP displaying different colors can constitute one pixel. For example, one pixel can include three sub-pixels, and the three sub-pixels SP can be red, green, and blue sub-pixels.

Although not shown in the figure, a plurality of first signal lines extending in the first direction X and a plurality of second signal lines extending in the second direction Y can be provided in the display area DA and can be electrically connected to the thin film transistor and/or the light-emitting diode of each sub-pixel SP.

Additionally, although not shown in the figure, first link lines and second link lines, which are electrically connected to the first signal lines and the second signal lines, respectively, can be provided in the non-display area NDA, and more particularly, in the non-display area NDA between the display area DA and the driving unit 20.

The driving unit 20 can be provided on one side of the display panel 10, for example, on the lower side of the display panel in the context of the figure, and can include a source printed circuit board 22 and at least one flexible printed circuit 24.

The flexible printed circuit 24 can be provided between the display panel 10 and the source printed circuit board 22, and the flexible printed circuit 24 can be attached to the non-display area NDA of the display panel 10.

The flexible printed circuit 24 can include a base film formed of a flexible material and a driver integrated circuit chip (driver IC chip) mounted on the base film. The flexible printed circuit 24 can generate a data signal for displaying an image and transmit the data signal to the display panel 10.

In the implementation of the present disclosure, the flexible printed circuit 24 can be a chip on film (COF) type. However, implementations of the present disclosure are not limited thereto. In other implementations, the flexible printed circuit 24 can be a chip on glass (COG) type or a tape carrier package (TCP) type.

Further, in the implementation of the present disclosure, three flexible printed circuits 24 can be provided, but implementations of the present disclosure are not limited thereto. The number of the flexible printed circuits 24 can vary.

The source printed circuit board 22 can include a circuit portion controlling the driver IC chip. For example, the source printed circuit board 22 can include a timing controller that receives an image signal and a plurality of timing signals from an external system, generate a plurality of control signals, and transmit the generated control signals to the driver IC chip.

In addition, the source printed circuit board 22 can include a touch driving circuit for detecting a touch.

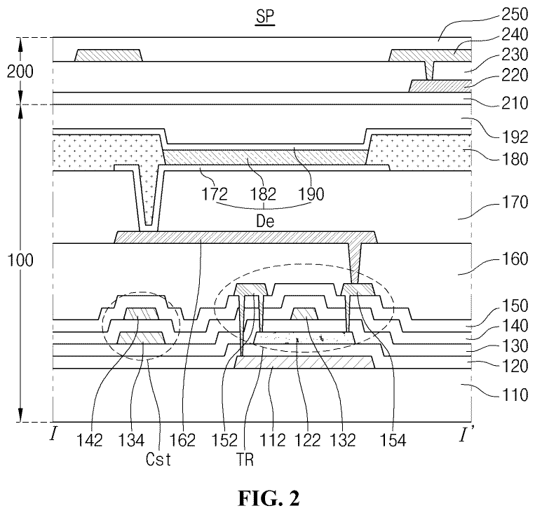

Meanwhile, although not shown in FIG. 1, a first sensing line (described in FIG. 2) extending substantially in the first direction and a second sensing line (described in FIG. 2) extending substantially in the second direction can be provided in the display area DA of the display panel 10.

For example, the first sensing line can include a receiver electrode, and the second sensing line can include a transmitter electrode. However, implementations of the present disclosure are not limited thereto. In other implementations, the first sensing line can include a transmitter electrode, and the second sensing line can include a receiver electrode.

The first sensing line and the second sensing line can cross each other to thereby form a sensing capacitor. The capacitance of the sensing capacitor can vary due to the input of the user, and a touch input can be detected from the amount of variation in the capacitance.

A first routing line RL1 and a second routing line electrically connected to the first sensing line and the second sensing line, respectively, can be provided in the non-display area NDA between the display area DA and the driving unit 20.

In some scenarios, since a signal of the first routing line RL1 connected to the first sensing line including the receiver electrode can be sensitive to surrounding signals, the signal of the first routing line RL1 can be coupled with signals of other lines or can be interfered with by signals of other lines. Accordingly, a ghost defect can occur, where the touch is recognized in an area other than the actual touch location, or the touch sensitivity can be reduced. That is, the signals of other lines can act as noise to the signal of the first routing line RL1.

Therefore, in the display device according to the implementation of the present disclosure, by providing a ground line GND in the non-display area NDA between the display area DA and the driving unit 20 and disposing the first routing line RL1 substantially between portions of the ground line GND, the signal of the first routing line RL1 can be prevented from being interfered with by signals adjacent thereto or being coupled with signals adjacent thereto.

In this case, the ground line GND can form a closed loop corresponding to each flexible printed circuit 24, and adjacent closed loops can be connected to each other corresponding to the source printed circuit board 22. Accordingly, the ground line GND can be provided so as to form a large closed loop such that a plurality of closed loops can be connected to each other corresponding to one source printed circuit board 22.

Further, in the display device according to the implementation of the present disclosure, a gate control line GCL can be provided in the display area DA and the non-display area NDA, and this will be described in detail later.

As such, the display device according to the implementation of the present disclosure can be provided with a sensor portion including the first and second sensing lines in the display panel 10 to thereby detect the touch input of the user and perform an operation corresponding thereto.

A cross-sectional configuration of the display device according to the implementation of the present disclosure will be described with reference to FIG. 2.

FIG. 2 is a cross-sectional view of a display device according to an implementation of the present disclosure. FIG. 2 corresponds to line I-I′ of FIG. 1 and shows a cross-section of one sub-pixel SP.

As shown in FIG. 2, a display panel 10 of the display device according to the implementation of the present disclosure can include a display portion 100 and a sensor portion 200 over the display portion 100.

The display portion 100 can include a thin film transistor TR and a light-emitting diode De over a substrate 110. The sensor portion 200 can include a bridge electrode 220 and a sensor electrode 240 constituting a sensor. In addition, the display portion 100 can further include a storage capacitor Cst.

Specifically, the substrate 110 of the display portion 100 can be formed of a transparent insulating material and, for example, can be a glass substrate or a plastic substrate. Polyimide can be used for the plastic substrate, and the plastic substrate can have a stacked structure including at least one polyimide layer and at least one inorganic layer. However, implementations of the present disclosure are not limited thereto.

A light-shielding pattern 112 can be provided over and in direct contact with the substrate 110. The light-shielding pattern 112 can be formed of a conductive material such as metal. The light-shielding pattern 112 can be formed of one or more of: aluminum (Al), copper (Cu), molybdenum (Mo), titanium (Ti), chromium (Cr), nickel (Ni), tungsten (W), and an alloy thereof. For example, the light-shielding pattern 112 can have a single-layered structure or a multiple-layered structure.

A barrier layer can be further provided between the substrate 110 and the light-shielding pattern 112. The barrier layer can be formed of an inorganic insulating material, such as silicon oxide (SiOx), silicon nitride (SiNx), or silicon oxynitride (SiON), and can be formed as a single layer or multiple layers.

A buffer layer 120 can be provided over the light-shielding pattern 112. The buffer layer 120 can be formed of an inorganic insulating material, such as silicon oxide (SiOx), silicon nitride (SiNx), or silicon oxynitride (SiON), and can be formed as a single layer or multiple layers.

A semiconductor layer 122 can be provided over the buffer layer 120. The semiconductor layer 122 can overlap the light-shielding pattern 112, and the light-shielding pattern 112 can block light incident on the semiconductor layer 122, and reduce or prevent the semiconductor layer 122 from deteriorating due to the light.

The semiconductor layer 122 can include a channel region of the central portion and source and drain regions on both sides of the channel region. The semiconductor layer 122 can be formed of an oxide semiconductor material. Alternatively, the semiconductor layer 122 can be formed of polycrystalline silicon. In this case, both end portions of the semiconductor layer 122 can be doped with impurities.

A gate insulation layer 130 can be provided over the semiconductor layer 122. The gate insulation layer 130 can be formed of an inorganic insulating material, such as silicon oxide (SiOx), silicon nitride (SiNx), or silicon oxynitride (SiON), and can be formed as a single layer or multiple layers.

A gate electrode 132 and a first capacitor electrode 134 can be provided over the gate insulation layer 130.

The gate electrode 132 can overlap the semiconductor layer 122 and can be disposed to correspond to the central portion of the semiconductor layer 122. Accordingly, the gate electrode 132 can overlap the light-shielding pattern 112.

The first capacitor electrode 134 can be spaced apart from the gate electrode 132. The first capacitor electrode 134 can also be spaced apart from the light-shielding pattern 112. However, implementations of the present disclosure are not limited thereto. In other implementations, the first capacitor electrode 134 can be in direct contact with the gate electrode 132 and be electrically connected to the gate electrode 132.

The gate electrode 132 and the first capacitor electrode 134 can be formed of a conductive material such as metal. The gate electrode 132 and the first capacitor electrode 134 can be formed of one or more of: aluminum (Al), copper (Cu), molybdenum (Mo), titanium (Ti), chromium (Cr), nickel (Ni), tungsten (W), and an alloy thereof. The gate electrode 132 and the first capacitor electrode 134 can have a single-layered structure or a multiple-layered structure.

A first interlayer insulation layer 140 can be provided over the gate electrode 132 and the first capacitor electrode 134. The first interlayer insulation layer 140 can be formed of an inorganic insulating material, such as silicon oxide (SiOx), silicon nitride (SiNx), or silicon oxynitride (SiON), and can be formed as a single layer or multiple layers.

A second capacitor electrode 142 can be provided over the first interlayer insulation layer 140. The second capacitor electrode 142 can overlap the first capacitor electrode 134 to thereby form the storage capacitor Cst.

The second capacitor electrode 142 can be formed of a conductive material such as metal. The second capacitor electrode 142 can be formed of one or more of: aluminum (Al), copper (Cu), molybdenum (Mo), titanium (Ti), chromium (Cr), nickel (Ni), tungsten (W), and an alloy thereof. For example, the second capacitor electrode 142 can have a single-layered structure or a multiple-layered structure.

A second interlayer insulation layer 150 can be provided over the second capacitor electrode 142. The second interlayer insulation layer 150 can be formed of an inorganic insulating material, such as silicon oxide (SiOx), silicon nitride (SiNx), or silicon oxynitride (SiON), and can be formed as a single layer or multiple layers.

A source electrode 152 and a drain electrode 154 can be provided over the second interlayer insulation layer 150. The source and drain electrodes 152 and 154 can be spaced apart from each other with the gate electrode 132 positioned therebetween and can be in contact with the both end portions of the semiconductor layer 122 through contact holes provided in the first and second interlayer insulation layers 140 and 150 and the gate insulation layer 130.

In addition, the source electrode 152 can be in contact with the light-shielding pattern 112 through a contact hole provided in the first and second interlayer insulation layers 140 and 150, the gate insulation layer 130, and the buffer layer 120.

The source and drain electrodes 152 and 154 can be formed of one or more of: aluminum (Al), copper (Cu), molybdenum (Mo), titanium (Ti), chromium (Cr), nickel (Ni), tungsten (W), and an alloy thereof. The source and drain electrodes 152 and 154 can have a single-layered structure or a multiple-layered structure.

The source and drain electrodes 152 and 154, the semiconductor layer 122, and the gate electrode 132 can form the thin film transistor TR.

Meanwhile, one of the first and second interlayer insulation layers 140 and 150 can be omitted, and in this case, the second capacitor electrode 142 can be provided of the same material and over the same layer as the source and drain electrodes 152 and 154.

A first planarization layer 160 can be provided over the source and drain electrodes 152 and 154. The first planarization layer 160 can eliminate a step difference due to the layers thereunder and can have a substantially flat top surface. The first planarization layer 160 can be formed of an organic insulating material such as photosensitive acrylic polymer (photo acryl).

A connection electrode 162 can be provided over the first planarization layer 160. The connection electrode 162 can be in contact with the drain electrode 154 through a contact hole provided in the first planarization layer 160.

The connection electrode 162 can overlap the thin film transistor TR and the storage capacitor Cst. However, implementations of the present disclosure are not limited thereto. In other implementations, the connection electrode 162 can overlap a part of the thin film transistor TR and be in spaced apart from the storage capacitor Cst.

The connection electrode 162 can be formed of a conductive material such as metal. The connection electrode 162 can be formed of one or more of: aluminum (Al), copper (Cu), molybdenum (Mo), titanium (Ti), chromium (Cr), nickel (Ni), tungsten (W), and an alloy thereof. For example, the connection electrode 162 can have a single-layered structure or a multiple-layered structure.

A second planarization layer 170 can be provided over the connection electrode 162. The second planarization layer 170 can eliminate a step difference due to the layers thereunder and can have a substantially flat top surface. The second planarization layer 170 can be formed of an organic insulating material such as photosensitive acrylic polymer (photo acryl).

Next, a first electrode 172 can be provided over the second planarization layer 170 and can be formed of a conductive material having relatively high work function. The first electrode 172 can be in contact with the connection electrode 162 through a contact hole provided in the second planarization layer 170. Accordingly, the first electrode 172 can be electrically connected to the drain electrode 154 through the connection electrode 162.

Alternatively, the connection electrode 162 and the second planarization layer 170 can be omitted. In this case, the first electrode 172 can be in direct contact with the drain electrode 154.

For example, the first electrode 172 can include a transparent conductive material such as indium tin oxide (ITO) or indium zinc oxide (IZO) or include titanium (Ti). However, implementations of the present disclosure are not limited thereto.

Meanwhile, the first electrode 172 can have a multi-layered structure including a material with relatively high reflectance. For example, the first electrode 172 can be formed as a structure having relatively high reflectance such as a triple-layered structure of titanium, aluminum, and titanium (Ti/Al/Ti), a triple-layered structure of indium tin oxide, aluminum, and indium tin oxide (ITO/Al/ITO), a triple-layered structure of indium tin oxide, silver, and indium tin oxide (ITO/Ag/ITO), or a triple-layered structure of indium tin oxide, silver alloy, and indium tin oxide (ITO/Ag alloy/ITO). Here, the silver alloy can be an alloy of silver-palladium-copper (APC).

A bank 180 of an organic insulating material can be provided over the first electrode 172. The bank 180 can overlap edges of the first electrode 172 and cover the edges of the first electrode 172. The bank 180 can expose a central portion of the first electrode 172.

A light-emitting layer 182 can be provided over the first electrode 172 exposed by the bank 180. The light-emitting layer 182 can emit one light of red, green, and blue colors.

The light-emitting layer 182 can include at least one hole auxiliary layer, at least one light-emitting material layer, and at least one electron auxiliary layer constituting one light-emitting unit.

The light-emitting material layer can include one of red, green, and blue luminescent materials. The luminescent material can be an organic luminescent material such as a phosphorescent compound or a fluorescent compound or can be an inorganic luminescent material such as a quantum dot.

The hole auxiliary layer can include at least one of a hole injection layer (HIL) and a hole transport layer (HTL). The electron auxiliary layer can include at least one of an electron injection layer (EIL) and an electron transport layer (ETL).

As shown in the figure, the light-emitting layer 182 can be disposed only over the first electrode 172 exposed by the bank 180. However, implementations of the present disclosure are not limited thereto. In other implementations, some of the light-emitting layer 182, for example, the light-emitting material layer can be disposed only over the first electrode 172, and the hole auxiliary layer and the electron auxiliary layer can be disposed substantially all over the substrate 110.

Alternatively, in other implementations, the light-emitting layer 182 can emit white light and can be provided on top and side surfaces of the bank 180, so that the light-emitting layer 182 can be disposed substantially all over the substrate 110. In this case, the light-emitting layer 182 can include a plurality of light-emitting units emitting light of different colors and being stacked. Each stack can include at least one hole auxiliary layer, at least one light-emitting material layer, and at least one electron auxiliary layer.

For example, the light-emitting layer 182 can have a stack structure in which two or more light-emitting units emitting light of different colors are stacked, and a charge generation layer (CGL) can be provided between two or more light-emitting units.

A second electrode 190 of a conductive material with relatively low work function can be provided over the light-emitting layer 182. The second electrode 190 can be disposed substantially all over the substrate 110.

The second electrode 190 can be formed of aluminum (Al), magnesium (Mg), silver (Ag), or an alloy thereof. In this case, the second electrode 190 can have a relatively thin thickness such that light from the light-emitting layer 182 can be transmitted therethrough. For example, the second electrode 190 can have a thickness of about 5 nm to about 10 nm, but implementations of the present disclosure are not limited thereto.

Alternatively, the second electrode 190 can be formed of a transparent conductive material such as indium gallium oxide (IGO) or IZO.

The first electrode 172, the light-emitting layer 182, and the second electrode 190 can constitute the light-emitting diode De. Here, the first electrode 172 can serve as an anode, and the second electrode 190 can serve as a cathode. However, implementations of the present disclosure are not limited thereto. In other implementations, the first electrode 172 can serve as a cathode, and the second electrode 190 can serve as an anode.

An encapsulation layer 192 can be provided over the second electrode 190 and disposed substantially all over the substrate 110. The encapsulation layer 192 can protect the light-emitting diode De from external moisture or oxygen. The encapsulation layer 192 can include at least one inorganic layer and at least one organic layer. Here, the organic layer can be a layer covering particles that are generated during the manufacturing process.

Meanwhile, although not shown in the figure, a capping layer can be provided between the second electrode 190 and the encapsulation layer 192. The capping layer can be formed of an insulating material having a relatively high refractive index. The wavelength of light traveling along the capping layer can be amplified by surface plasma resonance. Thus, the intensity of the peak can be increased, thereby improving the light efficiency in the display device. For example, the capping layer can be formed as a single layer of an organic layer or an inorganic layer, or can be formed as organic/inorganic stacked layers.

Next, a first sensor insulation layer 210 can be provided over the encapsulation layer 192. The first sensor insulation layer 210 can be a sensor buffer layer of the sensor portion 200. The first sensor insulation layer 210 can be formed of an inorganic insulating material, such as silicon oxide (SiOx), silicon nitride (SiNx), or silicon oxynitride (SiON), and can be formed as a single layer or multiple layers.

A bridge electrode 220 can be provided over the first sensor insulation layer 210. The bridge electrode 220 can overlap the bank 180 and be spaced apart from the light-emitting diode De.

The bridge electrode 220 can be formed of a conductive material such as metal. The bridge electrode 220 can be formed of one or more of: aluminum (Al), copper (Cu), molybdenum (Mo), titanium (Ti), chromium (Cr), nickel (Ni), tungsten (W), and an alloy thereof. For example, the bridge electrode 220 can have a single-layered structure or a multiple-layered structure.

A second sensor insulation layer 230 can be provided over the bridge electrode 220. The second sensor insulation layer 230 can be a sensor interlayer insulation layer. The second sensor insulation layer 230 can be formed of an organic insulating material such as photosensitive acrylic polymer (photo acryl).

A plurality of sensor electrodes 240 can be provided over the second sensor insulation layer 230. The plurality of sensor electrodes 240 can be selectively in contact with the bridge electrode 220 through a contact hole provided in the second sensor insulation layer 230.

Accordingly, the plurality of sensor electrodes 240 can be selectively connected to each other through the bridge electrode 220 in the first direction X and/or the second direction Y, thereby forming a first sensing line substantially extending in the first direction X and a second sensing line substantially extending in the second direction Y.

Namely, each of the first sensing line and the second sensing line can include a respective bridge electrode 220 and a respective sensor electrode 240.

The sensor electrode 240 can be formed of a conductive material such as metal. The sensor electrode 240 can be formed of one or more of: aluminum (Al), copper (Cu), molybdenum (Mo), titanium (Ti), chromium (Cr), nickel (Ni), tungsten (W), and an alloy thereof. For example, the sensor electrode 240 can have a single-layered structure or a multiple-layered structure.

A third sensor insulation layer 250 can be provided over the sensor electrode 240. The third sensor insulation layer 250 can be a sensor passivation layer. The third sensor insulation layer 250 can be formed of an inorganic insulating material, such as silicon oxide (SiOx), silicon nitride (SiNx), or silicon oxynitride (SiON), and can be formed as a single layer or multiple layers.

In addition, although not shown in FIG. 2, a protection layer can be provided over the third sensor insulation layer 250. The protection layer can be formed of an organic insulating material.

However, implementations of the present disclosure are not limited thereto. In other implementations, one of the third sensor insulation layer 250 and the protection layer can be omitted.

As such, by providing the sensor portion 200 over the display portion 100, the display device according to the implementation of the present disclosure can detect the touch input of the user and perform an operation corresponding thereto.

Meanwhile, referring to FIG. 1 again, the display device according to the implementation of the present disclosure can include the gate control line GCL.

The gate control line GCL can be provided in the non-display area NDA and be connected to the flexible printed circuit 24. The gate control line GCL can extend and also be provided in the display area DA. In this case, the gate control line GCL can be provided on each of both ends of the flexible printed circuit 24 and be symmetrical left and right in response to the flexible printed circuit 24.

The gate control line GCL can transmit a gate control signal from the source printed circuit board 22 to the display area DA. For example, the gate control signal can include a timing signal such as clock, a constant voltage, and so on.

In addition, although not shown in the figure, the display device according to the implementation of the present disclosure can include a gate driving circuit provided in the display area DA. The gate driving circuit can be disposed between adjacent sub-pixels SP and/or in the sub-pixel SP.

The gate driving circuit of the display area DA can be connected to the gate control line GCL and receive the gate control signal. The gate driving circuit can generate a gate signal using the gate control signal and transmit the generated gate signal to each sub-pixel SP.

The gate driving circuit provided in the display area DA can be a gate in active (GIA) type.

As such, in the display device according to the implementation of the present disclosure, since the gate driving circuit is provided in the display area DA and is not formed in the non-display area NDA, the area of the non-display area NDA can be decreased.

Accordingly, in the display device according to the implementation of the present disclosure, the bezel area can be minimized, and the area of the display area DA can be increased compared to the same size.

In some implementations, in the display device according to the implementation of the present disclosure, the gate control line GCL can cross and overlap at least one first routing line RL1. As described above, since the signal of the first routing line RL1 is sensitive to surrounding signals, the signal of the first routing line RL1 can be influenced by the gate control signal of the gate control line GCL, so the touch sensing characteristics can be degraded. That is, the touch performance can be deteriorated.

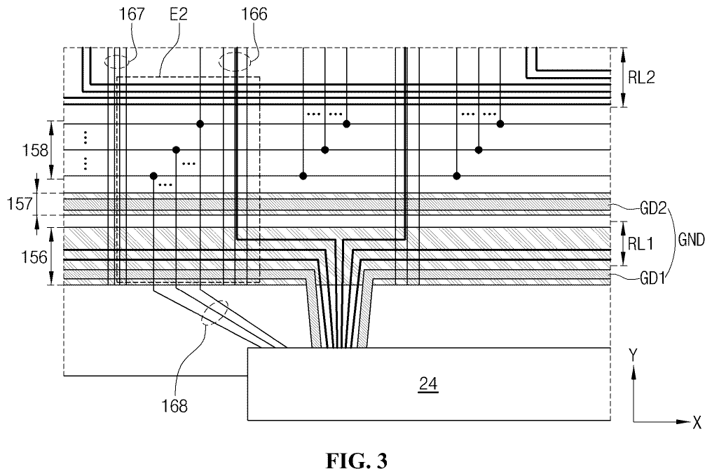

Accordingly, in the display device according to the implementation of the present disclosure, a shielding pattern can be provided between the gate control line GCL and the first routing line RL1 in a thickness direction, thereby preventing the touch sensing characteristics from being degraded. This will be described in detail with reference to FIGS. 3 to 6.

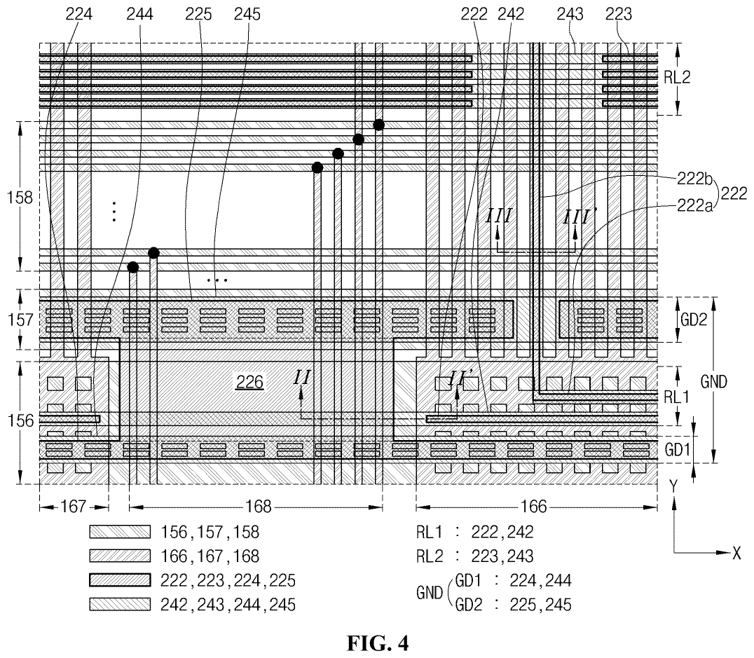

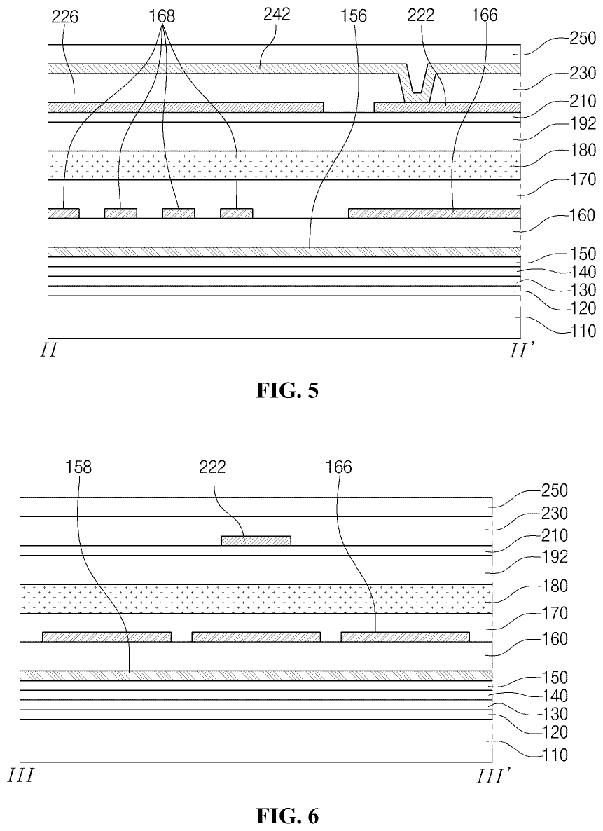

FIG. 3 and FIG. 4 are schematically enlarged plan views of a display device according to an implementation of the present disclosure, and FIG. 5 and FIG. 6 are cross-sectional views of the display device according to the implementation of the present disclosure. FIG. 3 is a view enlarging an area E1 of FIG. 1, FIG. 4 is a view enlarging an area E2 of FIG. 3, FIG. 5 is a cross-sectional view of a line II-II′ of FIG. 4, and FIG. 6 is a cross-sectional view of a line III-III′ of FIG. 4.

As shown in FIGS. 3 to 6, in the non-display area NDA of the display device according to the implementation of the present disclosure, a first horizontal power line 156, a second horizontal power line 157, a plurality of horizontal gate control lines 158, a plurality of first routing lines RL1, a plurality of second routing lines RL2, and a ground line GND can be provided to substantially extend in the first direction X, and a plurality of first vertical power lines 166, a plurality of second vertical power lines 167, and a plurality of vertical gate control lines 168 can be provided to substantially extend in the second direction Y.

The ground line GND can include a first ground line GD1 and a second ground line GD2 extending in the first direction X and being spaced apart from each other in the second direction Y. Both ends of the first ground line GD1 can be connected to respective ends of the second ground line GD2 to thereby form a closed loop.

The first routing line RL1 can be disposed between the first ground line GD1 and the second ground line GD2 in the second direction Y, and the second routing line RL2 can be disposed between the ground line GND and the display area DA in the second direction.

Each of the first routing line RL1, the second routing line RL2, the first ground line GD1, and the second ground line GD2 can have a double wiring structure including a lower line and an upper line provided over different layers. That is, the first routing line RL1 can include a plurality of first lower routing lines 222 and a plurality of first upper routing lines 242. The second routing line RL2 can include a plurality of second lower routing lines 223 and a plurality of second upper routing lines 243. The first ground line GD1 can include a first lower ground line 224 and a first upper ground line 244. The second ground line GD2 can include a second lower ground line 225 and a second upper ground line 245.

In addition, a shielding pattern 226 can be further provided between the first ground line GD1 and the second ground line GD2 in the second direction Y. The shielding pattern 226 can overlap the plurality of vertical gate control lines 168 and at least one first routing line RL1. The shielding pattern 226 can be formed of the same material and over the same layer as the first lower ground line 224 and the second lower ground line 225. The shielding pattern 226 can be connected to the first lower ground line 224 and the second lower ground line 225 to be formed as one body.

Specifically, the buffer layer 120, the gate insulation layer 130, the first interlayer insulation layer 140, the second interlayer insulation layer 150 can be sequentially provided over the substrate 110. The first horizontal power line 156, the second horizontal power line 157, and the plurality of horizontal gate control lines 158 can be provided over the second interlayer insulation layer 150.

The first horizontal power line 156, the second horizontal power line 157, and the horizontal gate control lines 158 can extend in the first direction X and be spaced apart from each other in the second direction Y. Here, the second horizontal power line 157 can be disposed between the first horizontal power line 156 and the horizontal gate control lines 158.

The first horizontal power line 156, the second horizontal power line 157, and the horizontal gate control lines 158 can be provided over the same layer as the source and drain electrodes 152 and 154 of FIG. 2, that is, over the second interlayer insulation layer 150 and can be formed of the same material as the source and drain electrodes 152 and 154.

For example, the first horizontal power line 156 can transmit a low potential voltage, and the second horizontal power line 157 can transmit a high potential voltage. However, implementations of the present disclosure are not limited thereto.

Next, the first planarization layer 160 can be provided over the first horizontal power line 156, the second horizontal power line 157, and the horizontal gate control lines 158. The first vertical power line 166, the second vertical power line 167, and the plurality of vertical gate control lines 168 can be provided over the first planarization layer 160.

The first vertical power line 166, the second vertical power line 167, and the plurality of vertical gate control lines 168 can extend in the second direction Y and can be spaced apart from each other in the first direction X.

Each of the first vertical power line 166 and the second vertical power line 167 can be provided in plural extending in the second direction Y and being spaced apart from each other in the first direction X. Ends of the first vertical power lines 166 can be connected to each other and formed as one body, and ends of the second vertical power lines 167 can be connected to each other and formed as one body. The first vertical power lines 166 and the second vertical power lines 167 can overlap the first horizontal power line 156 and the second horizontal power line 157.

The first vertical power lines 166 and the second vertical power lines 167 can be in contact with the first horizontal power line 156 through contact holes provided in the first planarization layer 160.

However, implementations of the present disclosure are not limited thereto. In other implementations, the first vertical power lines 166 can be in contact with the first horizontal power line 156, and the second vertical power lines 167 can be in contact with the second horizontal power line 157.

The plurality of vertical gate control lines 168 can be disposed between the first vertical power lines 166 and the second vertical power lines 167 in the first direction X. The plurality of vertical gate control lines 168 can extend in the second direction Y and be spaced apart from each other in the first direction X. The plurality of vertical gate control lines 168 can cross and overlap the first horizontal power line 156 and the second horizontal power line 157.

At least some of the plurality of vertical gate control lines 168 can have different lengths. The plurality of vertical gate control lines 168 can correspond to the plurality of horizontal gate control lines 158 one-to-one. The plurality of vertical gate control lines 168 can be in contact with the plurality of horizontal gate control lines 158 through contact holes provided in the first planarization layer 160, respectively.

The first vertical power lines 166, the second vertical power lines 167, and the vertical gate control lines 168 can be provided over the same layer as the connection electrode 162 of FIG. 2, that is, over the first planarization layer 160 and can be formed of the same material as the connection electrode 162.

The second planarization layer 170, the bank 180, and the encapsulation layer 192 can be sequentially provided over the first vertical power lines 166, the second vertical power lines 167, and the vertical gate control lines 168.

The first sensor insulation layer 210 can be provided over the encapsulation layer 192. The plurality of first lower routing lines 222, the plurality of second lower routing lines 223, the first lower ground line 224, the second lower ground line 225, and the shielding pattern 226 can be provided over the first sensor insulation layer 210.

Each of the first lower routing lines 222 can include a horizontal part 222a extending in the first direction X and a vertical part 222b extending in the second direction Y.

The horizontal parts 222a of the first lower routing lines 222 can overlap the first horizontal power line 156 and can be spaced apart from the second horizontal power line 157 and the horizontal gate control lines 158. In addition, the horizontal parts 222a of the first lower routing lines 222 can be spaced apart from the vertical gate control lines 168 and the shielding pattern 226.

The horizontal part 222a of at least one first lower routing line 222 can be separated to correspond to the vertical gate control lines 168, and the shielding pattern 226 can be disposed between the separated parts of the horizontal part 222a.

The vertical parts 222b of the first lower routing lines 222 can be connected to ends of the corresponding horizontal parts 222a and extend toward the display area DA. The vertical parts 222b of the first lower routing lines 222 can overlap one of the first vertical power lines 166.

The second lower routing lines 223 can extend in the first direction X and can be separated to correspond to the vertical parts 222b of the first lower routing lines 222. The vertical pars 222b of the first lower routing lines 222 can be disposed between the separated parts of the second lower routing lines 223. The second lower routing lines 223 can be spaced apart from the vertical parts 222b of the first lower routing lines 222.

The second lower routing lines 223 can cross and overlap some of the first vertical power lines 166, the second vertical power lines 167, and the vertical gate control lines 168.

The first lower ground line 224 can extend in the first direction X and overlap the first horizontal power line 156.

The second lower ground line 225 can extend in the first direction X and overlap the second horizontal power line 157. The second lower ground line 225 can be separated to correspond to the vertical parts 222b of the first lower routing lines 222. The vertical parts 222b of the first lower routing lines 222 can be disposed between the separated parts of the second lower ground line 225, and the second lower ground line 225 can be spaced apart from the vertical parts 222b of the first lower routing lines 222.

The shielding pattern 226 can be disposed between the first lower ground line 224 and the second lower ground line 225 in the second direction Y. The shielding pattern 226 can be connected to the first lower ground line 224 and the second lower ground line 225 and formed as one body.

The shielding pattern 226 can overlap the plurality of vertical gate control lines 168 between the first lower ground line 224 and the second lower ground line 225 and can be spaced apart from the first vertical power line 166 and the second vertical power line 167.

In addition, the shielding pattern 226 can partially overlap the first horizontal power line 156 and the second horizontal power line 157.

The first lower routing lines 222, the second lower routing lines 223, the first lower ground line 224, the second lower ground line 225, and the shielding pattern 226 can be provided over the same layer as the bridge electrode 220 of FIG. 2, that is, over the first sensor insulation layer 210. The first lower routing lines 222, the second lower routing lines 223, the first lower ground line 224, the second lower ground line 225, and the shielding pattern 226 can be formed of the same material as the bridge electrode 220.

Next, the second sensor insulation layer 230 can be provided over the first lower routing lines 222, the second lower routing lines 223, the first lower ground line 224, the second lower ground line 225, and the shielding pattern 226. The first upper routing lines 242, the second upper routing lines 243, the first upper ground line 244, and the second upper ground line 245 can be provided over the second sensor insulation layer 230.

The first upper routing lines 242 can extend in the first direction X and overlap the first lower routing lines 222, respectively. The first upper routing lines 242 can be in contact with the first lower routing lines 222 through contact holes provided in the second sensor insulation layer 230, respectively.

In addition, at least one first upper routing line 242 can cross and overlap the plurality of vertical gate control lines 168 and the shielding pattern 226. Here, the shielding pattern 226 can be disposed between the first upper routing line 242 and the plurality of vertical gate control lines 168 in a thickness direction, that is, a third direction perpendicular to the first direction X and the second direction Y.

The second upper routing lines 243 can extend in the first direction X and overlap the second lower routing lines 223, respectively. The second upper routing lines 243 can be in contact with the second lower routing lines 223 through contact holes provided in the second sensor insulation layer 230, respectively.

The second upper routing lines 243 can overlap the vertical parts 222b of the first lower routing lines 222 and overlap the first vertical power lines 166 and the second vertical power lines 167. In addition, the second upper routing lines 243 can overlap at least one vertical gate control line 168.

The first upper ground line 244 can extend in the first direction X and overlap the first lower ground line 224. The first upper ground line 244 can be in contact with the first lower ground line 224 through a contact hole provided in the second sensor insulation layer 230.

The first upper ground line 244 can cross and overlap the first vertical power lines 166, the second vertical power lines167, and the plurality of vertical gate control lines 168.

The second upper ground line 245 can extend in the first direction X and overlap the second lower ground line 225. The second upper ground line 245 can be in contact with the second lower ground line 225 through a contact hole provided in the second sensor insulation layer 230.

The second upper ground line 245 can cross and overlap the first vertical power lines 166, the second vertical power lines 167, and the plurality of vertical gate control lines 168. In addition, the second upper ground line 245 can overlap the vertical parts 222b of the first lower routing lines 222.

The first upper routing line 242, the second upper routing line 243, the first upper ground line 244, and the second upper ground line 245 can be provided over the same layer as the sensor electrode 240 of FIG. 2, that is, over the second sensor insulation layer 230 and can be formed of the same material as the sensor electrode 240.

Here, the first upper routing line 242, the second upper routing line 243, the first upper ground line 244, and the second upper ground line 245 can have wider widths than the first lower routing line 222, the second lower routing line 223, the first lower ground line 224, and the second lower ground line 225, respectively. However, implementations of the present disclosure are not limited thereto. In other implementations, the first upper routing line 242, the second upper routing line 243, the first upper ground line 244, and the second upper ground line 245 can have narrower widths than the first lower routing line 222, the second lower routing line 223, the first lower ground line 224, and the second lower ground line 225, respectively. Additionally, in other implementations, widths of the first upper routing line 242, the second upper routing line 243, the first upper ground line 244, and the second upper ground line 245 can be the same as widths of the first lower routing line 222, the second lower routing line 223, the first lower ground line 224, and the second lower ground line 225, respectively.

Next, the third sensor insulation layer 250 can be provided over the first upper routing lines 242, the second upper routing lines 243, the first upper ground line 244, and the second upper ground line 245.

As such, in the display device according to the implementation of the present disclosure, the shielding pattern 226 connected to the first and second ground lines GD1 and GD2 can be provided between the first routing line RL1 and the vertical gate control lines 168 crossing and overlapping each other, so that the touch sensing characteristics can be prevented from being degraded due to the gate control signal.

The shielding pattern 226 can be formed of the same material and on the same layer as the bridge electrode 220, thereby preventing a decrease in the touch sensing characteristics without increasing the number of manufacturing processes.

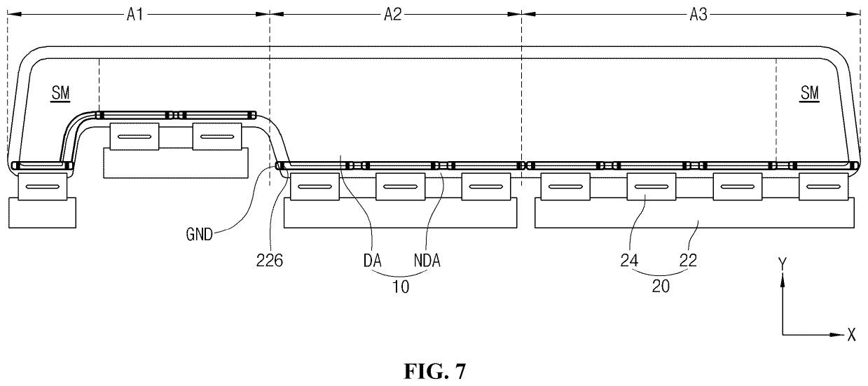

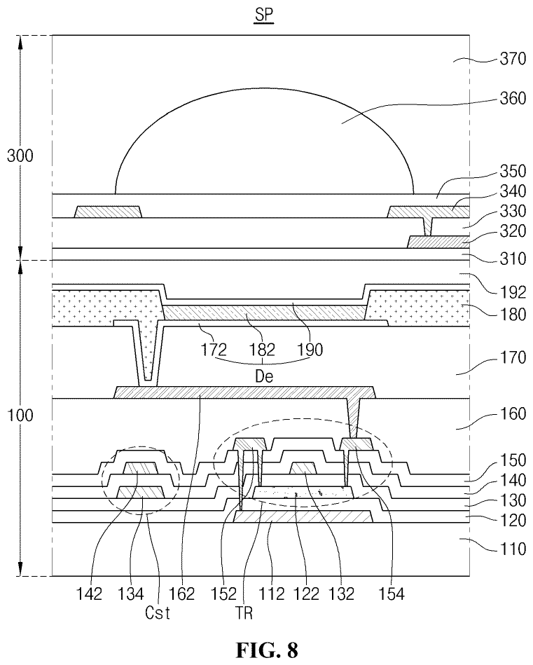

The display device according to the implementation of the present disclosure can be applied to a vehicle. A display device according to an implementation of the present disclosure applied to a vehicle will be described with reference to FIG. 7 and FIG. 8.

FIG. 7 is a schematic plan view of a display device according to an implementation of the present disclosure applied to a vehicle. The display device of FIG. 7 can have substantially the same configuration as that of the display device of FIGS. 1 to 6, except for a size and a sub-pixel configuration. The same parts as those of FIGS. 1 to 6 can be designated by the same or similar reference signs, and explanation for the same parts can be shortened or omitted.

In FIG. 7, the display device according to the implementation of the present disclosure can include the display panel 10 and the driving unit 20.

The display panel 10 can include the display area DA and the non-display area NDA. The display area DA can include first, second, and third regions A1, A2, and A3 sequentially arranged in the first direction X, and the second region A2 can be disposed between the first region A1 and the third region A3.

The first region A1 can correspond to a cluster and can provide information such as driving speed, RPM, engine temperature, and fuel amount. The second region A2 can correspond to a center information display (CID) and can provide various convenient functions such as audio, video, navigation, air conditioning, and Bluetooth. The third region A3 can correspond to a co-driver display (CDD) and can provide entertainment functions and/or seat information for a passenger seated in the front passenger seat.

Additionally, in the display device according to the implementation of the present disclosure, each of the first region A1 and the third region A3 can include side mirrors SM.

The driving unit 20 can include at least one source printed circuit board 22 and at least one flexible printed circuit 24 corresponding to each of the first, second, and third regions A1, A2, and A3.

For example, the driving unit 20 can include four source printed circuit boards 22 and ten flexible printed circuits 24. However, implementations of the present disclosure are not limited thereto. In other implementations, numbs of the source printed circuit boards 22 and the flexible printed circuits 24 can vary.

The source printed circuit board 22 can include a touch driving circuit corresponding to each of the first, second, and third regions A1, A2, and A3. That is, three touch driving circuits can be provided in the source printed circuit boards 22 corresponding to the first, second, and third regions A1, A2, and A3, respectively.

In this case, the ground line GND can form a closed loop corresponding to each of the first, second, and third regions A1, A2, and A3. In addition, the ground line GND can form a closed loop corresponding to each flexible printed circuit 24.

Meanwhile, as described above, the first routing line RL1 can be disposed in the closed loop of the ground line GND, and the gate control line GCL can cross and overlap the first routing line RL1. Here, the shielding pattern 226 connected to the ground line GND can be provided between the first routing line RL1 and the gate control line GCL. At least two shielding patterns 226 can be provided to correspond to each flexible printed circuit 24.

A cross-sectional configuration of the display device according to the implementation of the present disclosure applied to a vehicle will be described with reference to FIG. 8.

FIG. 8 is a schematic cross-sectional view of a display device according to an implementation of the present disclosure applied to a vehicle. FIG. 8 substantially shows one sub-pixel SP. The display device of FIG. 8 can have substantially the same configuration as that of the display device of FIG. 2, except for a lens. The same parts as those of FIG. 2 can be designated by the same or similar reference signs, and explanation for the same parts can be shortened or omitted.

As shown in FIG. 8, the display panel 10 of the display device according to the implementation of the present disclosure can include the display portion 100 and a light control portion 300 over the display portion 100.

The light control portion 300 can include a bridge electrode 320, a sensor electrode 340, and a lens 360. The bridge electrode 320 and the sensor electrode 340 can be selectively connected to form a sensor.

Specifically, a first sensor insulation layer 310 of the light control portion 300 can be provided over the encapsulation layer 192 of the display portion 100, and the bridge electrode 320 can be provided over the first sensor insulation layer 310.

A second sensor insulation layer 330 can be provided over the bridge electrode 320, and the sensor electrode 340 can be provided over the second sensor insulation layer 330. The sensor electrode 340 can be selectively in contact with the bridge electrode 320 through a contact hole provided in the second sensor insulation layer 330.

A third sensor insulation layer 350 can be provided over the sensor electrode 340, and the lens 360 can be provided over the third sensor insulation layer 350.

The lens 360 can be disposed to correspond to the light-emitting diode De. The lens 360 can allow light emitted from the light-emitting diode De to be output to the outside in a specific direction, thereby limiting a viewing angle. The lens 360 can be a hemispherical lens (e.g., a dome shaped lens) or a semi-cylindrical lens.

Next, a protection layer 370 can be provided over the lens 360 to protect the lens 360. The protection layer 370 can be formed of an organic insulating material and can have a substantially flat top surface. The refractive index of the protection layer 370 can be smaller than the refractive index of the lens 360. However, implementations of the present disclosure are not limited thereto.

The protection layer 370 can be formed of an organic insulating material such as photosensitive acrylic polymer (photo acryl), benzocyclobutene (BCB), polyimide (PI) or polyamide (PA), but implementations of the present disclosure are not limited thereto.

Meanwhile, although not shown in the figure, a polarizing plate can be provided over the protection layer 370. The polarizing plate can include a linear polarizing layer and a retardation layer. The polarizing plate can change the polarizing state of the external light incident on the display panel 10, so that the external light can be prevented from being output to the outside after being reflected in the display panel 10.

In the display device according to implementations of the present disclosure, by providing the lens 360 to correspond to the light-emitting diode De, light can be concentrated by the lens 360 and output to the outside in a specific direction, thereby limiting the viewing angle.

The display device according to implementations of the present disclosure can include the gate driving circuit in the display area, and the area of the non-display area can be decreased and the bezel area can be reduced. Such a display device according to implementations of the present disclosure can increase the area of the display area compared to the same size. Accordingly, the efficiency can be increased, thereby reducing the production power consumption and achieving the low power consumption.

In addition, by providing the sensor portion over the display portion of the display panel, the display device according to implementations of the present disclosure can be used as an output for displaying an image, and at the same time, can be used as an input for receiving user's commands by touching specific parts of the displayed image.

Further, the routing line of the non-display area connected to the sensing line of the sensor portion of the display area can be disposed in the closed loop of the ground line, so that occurrence of the signal interference or coupling can be prevented.

Moreover, by providing the shielding pattern between the routing line and the gate control line connected to the gate driving circuit of the display area, the touch performance can be prevented from being degraded due to the gate control signal.

In addition, by providing the light control portion over the display portion, the display device according to implementations of the present disclosure can selectively limit the viewing angle.

Various modifications and variations can be made in the electroluminescent display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device comprising:
a substrate including a display area and a non-display area;
a plurality of sub-pixels provided in the display area and arranged in a first direction and a second direction;
a first sensing line and a second sensing line provided in the display area; and
a first routing line and a second routing line provided in the non-display area, extending in the first direction, and electrically connected to the first sensing line and the second sensing line, respectively;
a gate control line provided in the non-display area and extending in the second direction;
a ground line provided in the non-display area and extending in the first direction; and
a shielding pattern connected to the ground line,
wherein the shielding pattern overlaps the first routing line and the gate control line and is disposed between the first routing line and the gate control line in a thickness direction.

2. The display device of claim 1, wherein the ground line includes a first ground line and a second ground line spaced apart from each other in the second direction, and
wherein the shielding pattern is disposed between the first ground line and the second ground line in the second direction.

3. The display device of claim 2, wherein the first routing line is disposed between the first ground line and the second ground line in the second direction, and
wherein the second routing line is disposed between the first and second ground lines and the display area in the second direction.

4. The display device of claim 2, wherein the shielding pattern is connected to the first ground line and the second ground line.

5. The display device of claim 4, wherein each of the first ground line and the second ground line includes a lower ground line and an upper ground line, and
wherein the shielding pattern is formed of a same material as the lower ground line.

6. The display device of claim 2, wherein both ends of the first ground line are connected to respective ends of the second ground line to thereby form a closed loop.

7. The display device of claim 6, further comprising:
a plurality of flexible printed circuits connected to the non-display area; and
a source printed circuit connected to the plurality of flexible printed circuits,
wherein the closed loop is provided to correspond to each of the plurality of flexible printed circuits, and adjacent closed loops are connected to each other.

8. The display device of claim 6, wherein the first routing line is disposed in the closed loop.

9. The display device of claim 1, wherein the first routing line includes a lower routing line and an upper routing line, and
wherein the lower routing line is spaced apart from the shielding pattern, and the upper routing line overlaps the shielding pattern.

10. The display device of claim 9, wherein the lower routing line is formed of a same material and on a same layer as the shielding pattern.

11. The display device of claim 1, wherein each of the first sensing line and the second sensing line includes a bridge electrode and a sensor electrode connected to the bridge electrode.

12. The display device of claim 11, wherein the shielding pattern is formed of a same material and on a same layer as the bridge electrode.

13. The display device of claim 1, further comprising a lens over the first and second sensing lines.

14. The display device of claim 1, further comprising a gate driving circuit provided in the display area and connected to the gate control line,
wherein the gate driving circuit receives a gate control signal from the gate control line, generates a gate signal using the gate control signal, and transmits the generated gate signal to each of the plurality of sub-pixels.
